(19) United States
(12) Patent Application Publication
(10) Pub. No.: US 2006/0223261 A1
(43) Pub. Date: Oct. 5, 2006

(54) CMOS-based low ESR capacitor and ESD-protection device and method

(75) Inventors: John Jorgensen, Los Gatos, CA (US); Harry Gee, Sunnyvale, CA (US)

Correspondence Address: PILLSBURY WINTHROP SHAW PITTMAN LLP, P.O. BOX 10500, MCLEAN, VA, 22102, US

(73) Assignee: California Micro Devices Corporation, Milpitas, CA (US)

(21) Appl. No.: 11/097,528

(22) Filed: Mar. 31, 2005

(51) Int. Cl. H01L 21/8242; H01L 21/331

(52) U.S. Cl. 438/244

(57) ABSTRACT

A method for fabricating a low dynamic resistance capacitor is an integrated circuit using conventional CMOS processing steps, where in one implementation the structure provides the additional feature of a Zener diode capable of offering ESD protection.

### FIELD OF THE INVENTION

The present invention relates to complimentary metal oxide semiconductor devices, and more particularly relates to devices and methods for fabricating a capacitive element operable at high frequencies using CMOS fabrication techniques. The invention also relates to ESD protection devices and methods using CMOS techniques.

### BACKGROUND OF THE INVENTION

Electronic circuits frequently make use of capacitors for numerous purposes, including filters as just one example of in a long list of uses. It is desirable to fabricate such capacitors integrally with the remaining devices that form the electronic circuit. This is particularly true for circuits comprised of solid state devices, which make up the vast majority of modern electronic circuits. In addition, the majority of modern circuits using solid state devices include devices fabricated using CMOS techniques. However, various limitations have made it difficult to fabricate capacitors integrally with CMOS transistors and similar devices, and particularly capacitors intended to operate at high frequency. Among these has been the existence of a resistor which is effectively connected in series with a capacitor formed in accordance with prior art techniques and significantly limits the application of such capacitive devices.

Such a prior art arrangement is shown in FIG. 1A, in which an epitaxial layer 100 of P− material is formed over a conventional substrate 110 of P type material. Conventional P+ depositions 120A-B are formed into the epitaxial layer 100, and an oxide layer 130, typically thought of as a gate oxide, is formed over the gap 140 between the P+ depositions 120A-B and also typically extends over a portion of those P+ depositions, as illustrated. A metal layer 150 is then formed over the oxide layer 130 to serve as one plate of a capacitor, with the oxide as the insulator. The other contact is made through the substrate and epitaxial layer. The resulting capacitor can be represented as shown in FIG. 1B, in which the capacitor 170 is connected in series with a resistor 180. The resistor 180 is typically in the magnitude of at least twenty to on the order of one thousand ohms or more.

As a result, there has been a need for a capacitor suitable for high frequency operation and capable of being fabricated through conventional CMOS techniques.

In addition, CMOS devices are susceptible to damage from electrostatic discharge, or ESD. While numerous techniques have been developed to protect CMOS devices, there has been a need for an ESD-protection device and method which could be fabricated through simple CMOS techniques.

### SUMMARY OF THE INVENTION

The present invention provides a capacitive element or device capable of operation at high frequency, for example on the order of three Gigahertz or less, and capable of being fabricated using CMOS techniques. The invention includes providing a P doped substrate onto which a P− epitaxial layer (“epi”) has been deposited. Then, a P doped sinker deposition is formed which penetrates through the epi to electrically connect to the substrate. Standard P+ depositions are then formed within the sinker deposition, characteristic of the source and drain depositions typical of many types of CMOS transistors.

In a first embodiment, a thin silicon oxide layer is formed above the sinker, and typically between the two P+ depositions. A metal layer is then formed atop at least a portion of the oxide layer. Electrical contacts may then be made in any suitable manner to the substrate and to the metal layer. A capacitor is formed by the sandwich of the metal layer, silicon oxide and the sinker deposition connected to the substrate. The value of the capacitor may be varied by the area (a design criteria) and the oxide thickness (a process criteria). While the design criteria may be readily changed, the process criteria frequently would not be changed to avoid impacting the remaining processing.

In an alternative arrangement, the metal layer and oxide layers are not required. Instead, an N+ deposition is formed within the sinker area, and the boundary between the N+ region and the sinker forms a capacitive element. It will also be noted that the combination of the N+ region within the P doped sinker region forms a diode, which may be configured to provide protection against electrostatic discharge. In at least some implementations of the present invention the diode will have a breakdown voltage on the order of six to nine volts, and a series resistance which is typically less that five ohms.

These and other features of the invention will be better understood from the following detailed description of the invention, taken together with the attached Figures.

### THE FIGURES

FIGS. 1A and 1B [PRIOR ART] illustrate in cross-sectional side view a prior art design and its electrical representation.

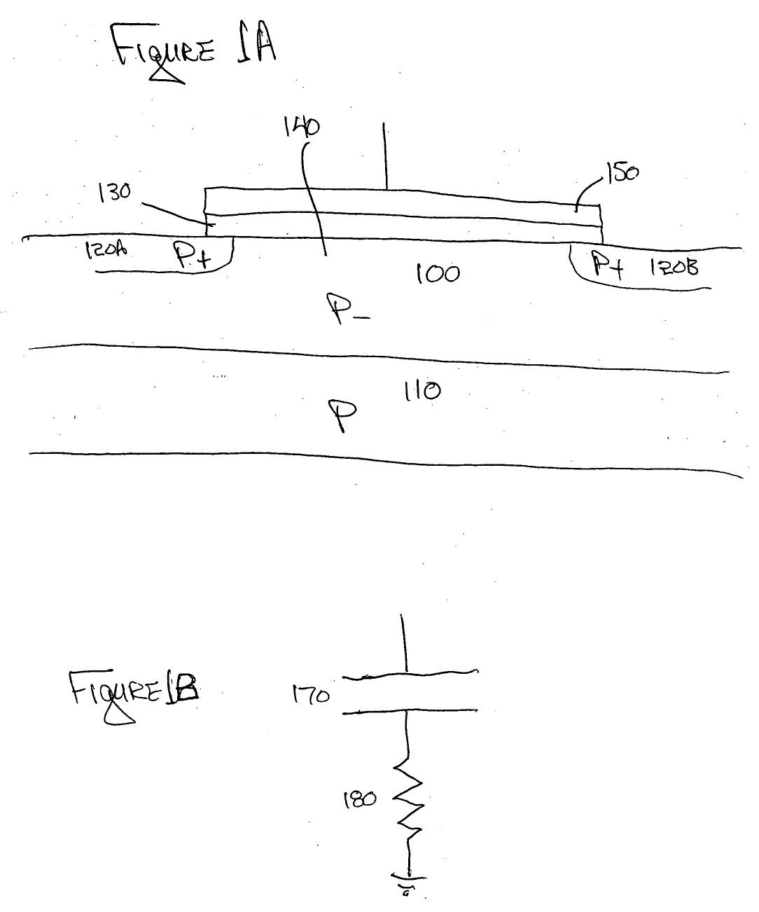

FIG. 2 illustrates in cross-sectional side view a first embodiment of the present invention.

FIG. 3 illustrates an electrical schematic representation of the capacitor of FIG. 2.

FIG. 4 illustrates in cross-sectional side view a second embodiment of the present invention.

FIG. 5 illustrates an electrical schematic representation of the capacitor of FIG. 4, and the diode which provides ESD protection.

FIG. 6 illustrates in flow diagram form the fabrication steps for forming the structure of FIG. 4.

### DETAILED DESCRIPTION OF THE INVENTION

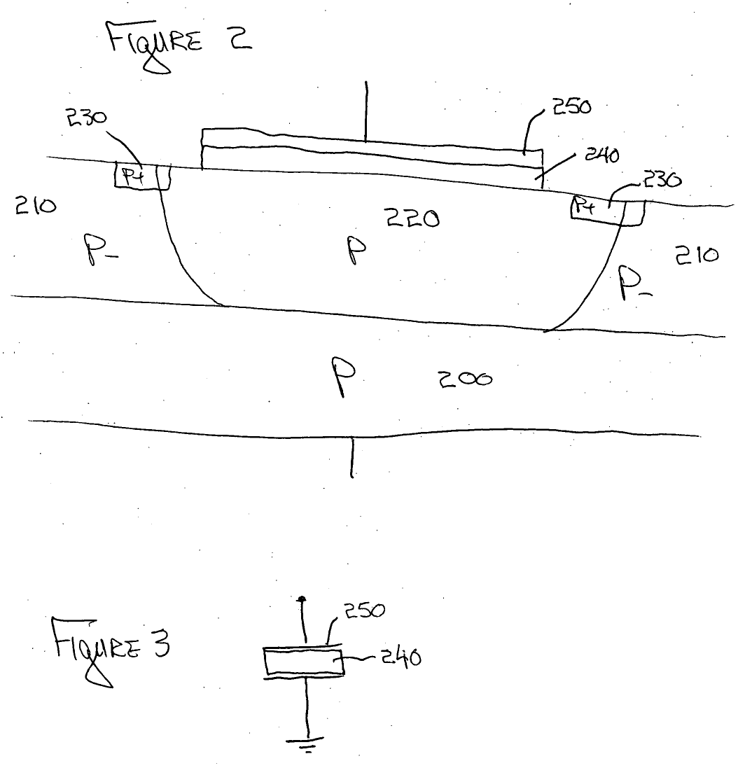

Referring first to FIG. 2, a first implementation of the invention is illustrated. A substrate 200 is formed of P doped material. An epitaxial layer 210 is formed in a conventional manner atop the substrate 200, typically of P− material. Using CMOS fabrication techniques, a P type sinker region 220 is formed into the epitaxial layer 210 until it electrically contacts the substrate 200. Then, again using CMOS fabrication techniques, a pair of P+ depositions 230A-B are formed in the sinker region 220, at the relatively outer edges thereof. The P+ depositions, while not necessarily required for all embodiments, can be provided to improve the contact to the substrate because they are a somewhat higher concentration than the sinker concentration. These additional depositions are “free” in terms of processing steps, because they are formed from the same diffusion used for making the PMOS device.

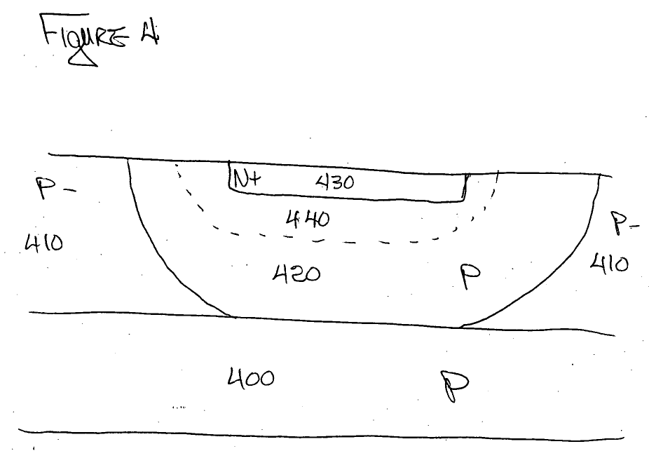

An oxide layer 240 is formed over the sinker region in a conventional manner, and a metal layer 250 is formed atop the oxide layer, also in a conventional manner. A contact is formed in electrical connection with the metal layer 250, and another on the back of the substrate 200, such that the metal layer, oxide and substrate form a capacitor 300 as represented electrically in FIG. 3.

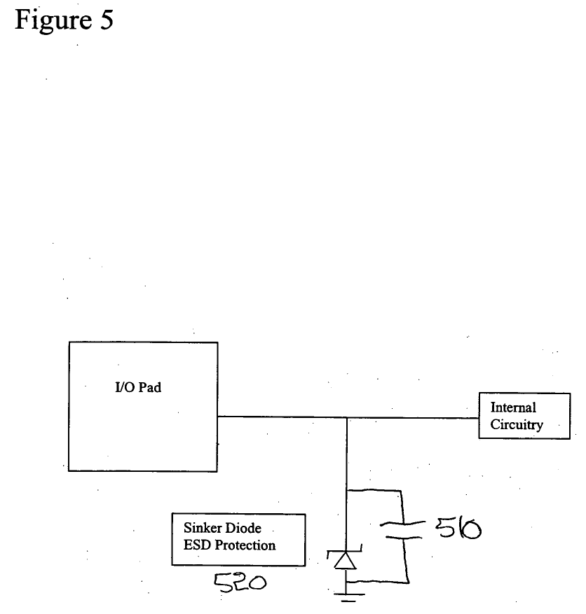

An alternative arrangement to the structure of FIG. 2 is illustrated in FIG. 4, in which a conventional P type substrate 400 is provided, again with an epitaxial layer 410 of P− material formed thereon in a conventional manner. Using CMOS fabrication techniques, a P type sinker deposition 420 is formed into and through the epitaxial layer 410 until the sinker deposition region electrically contacts the substrate 400.

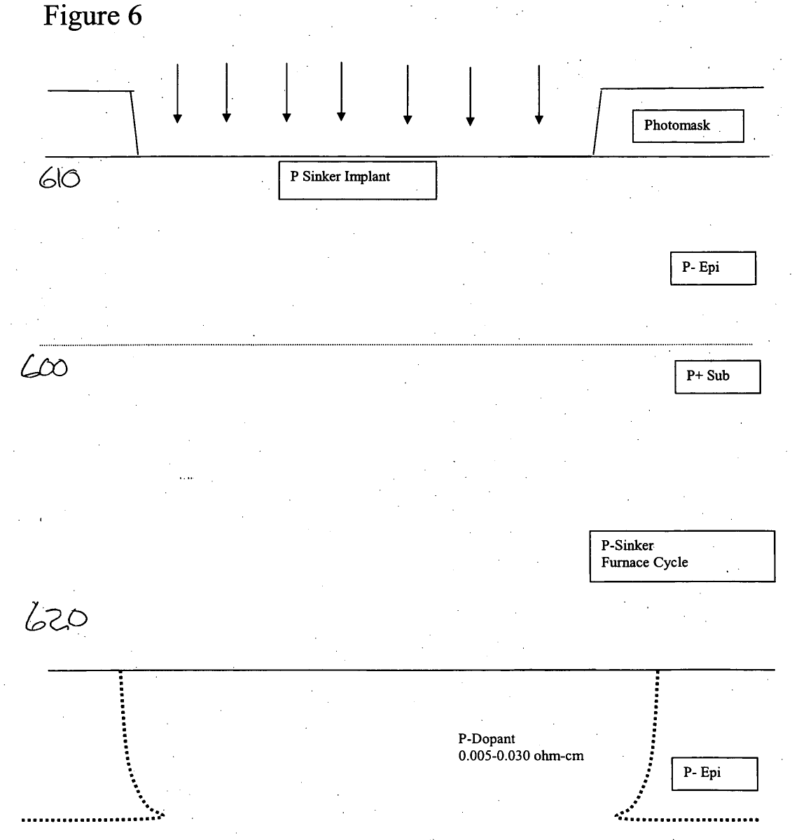

Then, again using CMOS techniques, an N+ deposition 430 is formed within the sinker region 420. By reverse biasing the junction of the N+ deposition 430 and the P sinker region, a charge layer 440 is formed therebetween, which is represented electrically as a capacitor 510 in FIG. 5, where the capacitor again has a low electrostatic resistance. In addition, a Zener diode 520 is also formed as represented electrically FIG. 5, which provides the additional feature of protection from electrostatic discharge. It has been determined that the implementation of the invention shown in FIG. 2 offers somewhat better linearity than the design of FIG. 4, but the design of FIG. 4 offers the additional feature of ESD protection.

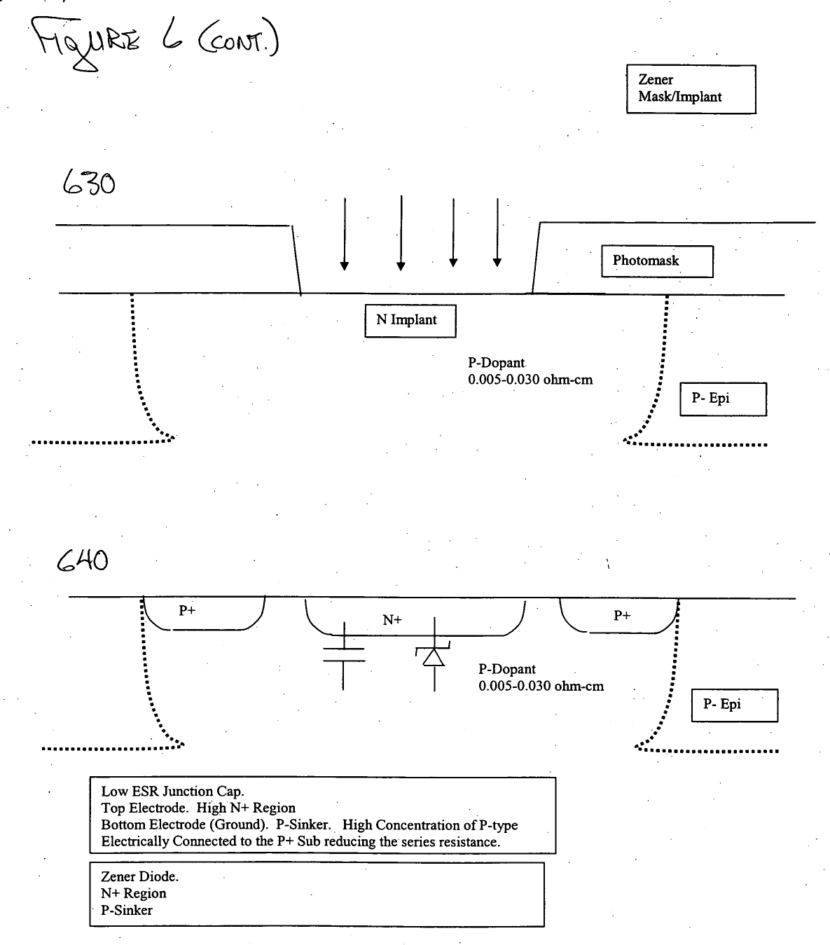

One example of a process flow for the fabrication of the invention can be appreciated from FIG. 6. At step 600, a P+ substrate is provided which can have the characteristic of 0.008 to 0.020 ohm-cm, with a P− epitaxial layer formed thereon of 5-15 μm thick and on the order of 1-50 ohm-cm. At step 610, a P type implant is formed in the epi layer where the dose can range from low E14 to mid E15, with the particular dose varying depending upon the epi thickness and the heat cycles. The goal is to achieve a dopant concentration generally in the range of 1E17 to mid E18, although these limits are not fixed. The dose can be applied using, for example, ion implantation. Low variation of the p-type during processing will permit tighter control of the Zener breakdown voltage and the value of the capacitor formed by the charge layer at the N+/P− region.

Next, at step 620, a high temperature drive is applied, typically on the order of 1125-1200 C for several hours. The objective is to diffuse the P+ dopant applied in step 610 through the P− epi to the P+ substrate, with a reasonably uniform surface concentration. It will be appreciated that these relatively high temperatures and relatively long drive times can be adjusted significantly, as long as appropriately low impedance electrical connection is made between the P+ sinker region and the substrate.

Then, at step 630, the zener is formed through conventional masking and implanting steps. In particular, an N-type implant is implanted into the P sinker, using a dose generally in the range of low E15 to low E16; this forms the N+ region of the Zener diode. The N+ region is typically formed in a conventional manner using CMOS or NMOS process flow.

Then, at step 640, conventional connections are made to N+ region and the P+ sinker. Connections to the P+ sinker can be made, for example, by a P+ deposition or by backside contacts.

It will be appreciated from the foregoing that the low dynamic resistance capacitor/Zener diode structure of FIG. 4 can be fabricated using a simple and inexpensive four mask process, making the fabrication of the invention attractive for numerous applications. If desired, the structure of the invention can be fabricated under a bonding pad for higher density, although it need not be positioned in such a location.

The breakdown voltage of the Zener diode, typically in the range of 5-8 volts, can be modified by adjusting the concentration of the P type sinker. By providing low series resistance, the device can sink high currents during an ESD event, thus ensuring that the voltage does not increase to dangerous levels that can damage gate oxides, metal lines, semiconductor devices, and so on. The device can also be scaled in area size to optimize the use of space on the die, as well as meeting ESD requirements.

Set forth in Table 1, below, are a series of examples of the variation of the Zener breakdown voltage at various doses and intensities, and drive times and temperatures.

| | | | | Bvzeber_{—} | Bvzeber_{—} |
|---|---|---|---|---|---|
| Sinker Drive | | | | 1 uA | 1 mA |
| 1150 C., | 100 | min | B+ 180 Kev 7.0E14 | 5.93 | 6.07 |
| | | | | 6.05 | 6.1 |
| | | | | 6.05 | 6.1 |
| | | | | 6.05 | 6.1 |
| | | | | 6.04 | 6.09 |
| 1150 C., | 100 | min | B+ 180 Kev 3.0E14 | 7.43 | 7.44 |
| | | | | 7.43 | 7.47 |
| | | | | 7.46 | 7.47 |
| | | | | 7.39 | 7.45 |
| | | | | 7.12 | 7.46 |
| 1150 C., | 80 | min | B+ 180 Kev 1.5E14 | 8.81 | 9.09 |
| | | | | 9.09 | 9.1 |
| | | | | 9.14 | 9.15 |
| | | | | 9.11 | 9.13 |
| | | | | 9.09 | 9.11 |
| 1150 C., | 100 | min | B+ 180 Kev 3.0E14 | 7.43 | 7.44 |
| | | | | 7.45 | 7.46 |
| | | | | 7.45 | 7.48 |
| | | | | 7.44 | 7.45 |
| | | | | 7.21 | 7.46 |
| 1150 C., | 80 | min | B+ 180 Kev 7.0E14 | 6 | 6.06 |
| | | | | 5.94 | 6.08 |
| | | | | 6.01 | 6.07 |
| | | | | 5.96 | 6.07 |
| | | | | 5.98 | 6.07 |
| 1150 C., | 80 | min | B+ 180 Kev 7.0E14 | 6 | 6.06 |
| | | | | 5.99 | 6.07 |
| | | | | 6.04 | 6.09 |
| | | | | 6.02 | 6.07 |
| | | | | 5.87 | 6.06 |
| 1150 C., | 100 | min | B+ 180 Kev 3.0E14 | 7.32 | 7.42 |
| | | | | 7.26 | 7.44 |
| | | | | 5.86 | 7.46 |
| | | | | 7.28 | 7.44 |
| | | | | 7.44 | 7.45 |
| 1150 C., | 100 | min | B+ 180 Kev 3.0E14 | 7.3 | 7.45 |
| | | | | 7.31 | 7.45 |
| | | | | 7.45 | 7.47 |
| | | | | 7.43 | 7.45 |
| | | | | 7.45 | 7.47 |
| 1150 C., | 80 | min | B+ 180 Kev 1.5E14 | 9.09 | 9.13 |
| | | | | 9.05 | 9.15 |
| | | | | 9.18 | 9.2 |
| | | | | 9.13 | 9.17 |
| | | | | 9.14 | 9.16 |
| 1150 C., | 80 | min | B+ 180 Kev 1.5E14 | 9.11 | 9.13 |
| | | | | 9.14 | 9.16 |
| | | | | 9.18 | 9.2 |
| | | | | 9.15 | 9.17 |
| | | | | 9.14 | 9.16 |
| 1150 C., | 80 | min | B+ 180 Kev 7.0E14 | 5.87 | 6.07 |
| | | | | 5.84 | 6.09 |
| | | | | 6.05 | 6.1 |
| | | | | 6.04 | 6.09 |
| | | | | 6.03 | 6.09 |
| 1150 C., | 100 | min | B+ 180 Kev 1.5E14 | 8.43 | 9.13 |
| | | | | 9.13 | 9.14 |
| | | | | 9.16 | 9.18 |
| | | | | 9.14 | 9.16 |
| | | | | 9.12 | 9.14 |

Having fully described a preferred embodiment of the invention and various alternatives, those skilled in the art will recognize, given the teachings herein, that numerous alternatives and equivalents exist which do not depart from the invention. It is therefore intended that the invention not be limited by the foregoing description, but only by the appended claims.

We claim:

1. A method for fabricating a capacitor in an integrated circuit comprising the steps of
providing a substrate having a first dopant concentration and an epitaxial layer thereon at a relatively lower dopant concentration,
forming by conventional CMOS process, in the epitaxial layer, a third dopant region having a dopant concentration higher than the dopant concentration in the epitaxial layer and substantially the same dopant concentration as the first dopant concentration,
causing the third dopant region to be driven into electrical connection with the substrate,
forming an oxide layer over the third region through conventional CMOS processing,
forming a metal layer over at least a portion of the oxide layer, and
providing contacts to the metal layer and the substrate such that the metal layer, oxide and substrate form a capacitor operable at frequencies up to on the order of three Gigahertz.

2. The method of claim 1 further including the step of forming at least one fourth dopant regions within the third dopant region, wherein the dopant concentration in the fourth dopant region is higher than the dopant concentration in the third dopant region, the fourth dopant region being formed by the same diffusion as required for forming a PMOS device in a CMOS process.

3. A method for fabricating ESD protection in an integrated circuit comprising the steps of
providing a substrate having a first dopant concentration and an epitaxial layer thereon at a relatively lower dopant concentration,
forming by conventional CMOS process, in the epitaxial layer, a third dopant region having a dopant concentration higher than the dopant concentration in the epitaxial layer and substantially the same dopant concentration as the first dopant concentration,
causing the third dopant region to be driven into electrical connection with the substrate,
forming, within the third dopant region, a fourth dopant region of a characteristic opposite to the characteristic of the third dopant region,
forming a metal layer over at least a portion of the oxide layer, and
providing contacts to the metal layer and the substrate such that the metal layer, oxide and substrate from a Zener diode with low series resistance.

4. The method of claim 3 wherein the ESD protection also forms a junction capacitor.
